(19) United States
(12) Patent Application Publication
(10) Pub. No.: US 2010/0025696 A1
(43) Pub. Date: Feb. 4, 2010

(54) Process for Producing a Silicon Carbide Substrate for Microelectric Applications

(76) Inventors: Giuseppe Abbondanza, San Giovanni La Punta (CT) (IT); Danilo Crippa, Novara(NO) (IT)

Correspondence Address: Brannen Law Office, LLC;Nicholas A. Brannen, 104 S. Main Street, Suite #506, Fond du Lac, WI, 54935, US

(21) Appl. No.: 12/442,705

(22) PCT Filed: Sep. 19, 2007
(86) PCT No.: PCT/IB07/02704

§ 371 Date: Mar. 24, 2009

(30) Foreign Application Priority Data
Sep. 25, 2006 (IT) MI2006A001809

(51) Int. Cl. H01L 29/24; H01L 29/205; C30B 23/02

(52) U.S. Cl. 257/77; 257/76; 117/88; 257/194; 257/E29.091; 257/E29.104

(57) ABSTRACT

The process according to the present invention is adapted to produce a silicon carbide substrate for microelectronic applications; it comprises the following steps:
a) providing a conductive silicon carbide wafer, and
b) growing an epitaxial layer of intrinsic silicon carbide on said wafer.

This application is being filed in the United States for the national phase of international application number PCT/IB2007/002704 filed on 19 Sep. 2007 (publication number WO 2008/038084 A1), claiming priority on prior application M12006A001809 filed in Italy 25 Sep. 2006, the contents of each being hereby incorporated herein by reference.

### DESCRIPTION

The present invention relates to a process for producing a silicon carbide substrate for microelectronic applications.

The microelectronics industry, in particular the field of electronic devices such as HEMTs [High Electron Mobility Transistors], which are adapted to operate at very high frequencies (e.g. within the microwave frequency range), needs to have semi-insulating silicon carbide substrates available on which to provide the actual structure of the device.

A similar need is also felt for high-energy radiation sensors, in particular X-ray sensors.

To this end, semi-insulating silicon carbide wafers are currently used; however, these wafers are very costly and not easily available, in addition to suffering from non-negligible crystallographic defectiveness. In X-ray sensors, this defectiveness is such that the sensor turns out to be almost ineffective.

It is the general object of the present invention to provide a process for producing silicon carbide substrates which overcomes the drawbacks of the prior art, in particular a simple, low-cost process allowing to obtain a low degree of crystallographic defectiveness.

Said object is achieved by the process according to the appended claim 1; other advantageous aspects of said process are set out in dependent claims, which are intended as an integral part of the present description.

The present invention is based on the idea of using a conductive silicon carbide wafer on which an epitaxial layer of intrinsic silicon carbide is grown which, when made properly, is semi-insulating. By so doing, a substrate is obtained which offers a semi-insulating silicon carbide region to the microelectronic structures provided thereon.

The cost of such a substrate is relatively low; in fact, conductive silicon carbide wafers are largely available on the market and are relatively cheap. Moreover, since it is a homoepitaxial process, the quality of such a substrate, in particular of the intrinsic silicon carbide layer, is very good.

According to further aspects, the present invention also relates to a silicon carbide substrate and to an electronic device having the features set out in the appended claims, which are intended as an integral part of the present description.

The present invention will become more apparent from the following description.

In general, the process according to the present invention is adapted to provide a silicon carbide substrate for microelectronic applications. Said process comprises the following steps:

a) providing a conductive silicon carbide wafer, and

b) growing an epitaxial layer of intrinsic silicon carbide on said wafer.

If made properly, the epitaxial layer of intrinsic silicon carbide is semi-insulating as well as free from any impurities (unintentional doping of less than 1.0E+14=10⁺¹⁴ per cubic centimetre) or crystallographic defects, and therefore this process provides an element which can be used as a semi-insulating silicon carbide substrate even for electronic devices such as HEMTs, which are adapted to operate at very high frequencies (e.g. within the microwave frequency range), or high-energy radiation sensors, in particular X-ray sensors.

The cost of said element is somewhat higher than that of a simple conductive silicon carbide wafer, but is much lower than that of a semi-insulating silicon carbide wafer.

Said process is of the homoepitaxial type, that is, one in which both overlaid materials are the same (i.e. silicon carbide); thus, the quality of the obtained substrate, in particular of the layer of intrinsic silicon carbide, is very good because any defects due to “mismatching” between the crystalline reticula of the two overlaid materials are minimized.

Of course, these two process steps are carried out in the order specified above. However, it must be remarked that additional steps may be carried out in between; for example, one or more “buffer” layers may be provided in order to improve the crystallographic quality of the grown epitaxial layer even further.

Process step b) is typically carried out through a CVD [Chemical Vapour Deposition] technique, i.e. a method of chemical deposition from the vapour phase; advantageously, this growth is accomplished at a temperature between 1,500° C. and 1,700° C. and a pressure between 100 mbar and 400 mbar; during experimental tests, growth speeds of up to 150 microns/hour were used; in any case, speeds of several tens of microns/hour can normally be used.

Process step b) is advantageously carried out without using or adding any substances adapted to compensate for any unintentional doping species in the grown layer. This requires the use of an epitaxial reactor having very good control over the substances present in the reaction chamber. The structures of a number of suitable reactors are described and illustrated schematically in the international patent applications WO2004/053187, WO2004/053188, WO2004/053189, WO2005/121417, WO2006/024572, WO2006/108783, WO2007/010568, WO2007/088420.

A first practice which is useful for obtaining a good intrinsic layer provides for heating the reaction chamber (wherein conductive silicon carbide wafers have been previously placed) to a temperature of about 1,000° C.-1,200° C. and reducing the pressure in the chamber considerably, e.g. to less than 1.0E−5=10⁻⁵ mbar, or more preferably to less than 1.0E−6=10⁻⁶ mbar, before starting the epitaxial growth; any doping substances (in particular nitrogen, which has a doping effect on silicon carbide) are thus expelled through the drain outlets, thereby reducing the probability that said substances are incorporated into the layer.

A second practice which is useful for obtaining a good intrinsic layer provides for setting and/or controlling the C/Si ratio to a high value, in particular higher than 0.4 and lower than 1.5, thereby limiting the incorporation into the layer of any residual doping substances (in particular nitrogen) in the chamber.

A third practice which is useful for obtaining a good intrinsic layer provides for setting and/or controlling the growth speed to a high value, in particular 50-150 microns/hour, preferably 80-100 microns/hour, and regulating not only the flows of precursor gases, but also the Si/H and C/Si ratios, thereby limiting the incorporation into the layer of any residual doping substances (in particular nitrogen) in the chamber.

A fourth practice which is useful for obtaining a good intrinsic layer provides for using a silicon precursor containing chlorine, preferably trichlorosilane [TCS], or a silicon precursor containing no chlorine, preferably silane [SiH4], together with hydrochloric acid [HCl] so as to minimize the formation of silicon clusters, thus maximizing the quantity of silicon available for the deposition of silicon carbide and increasing the growth speed; as to the carbon precursor, a hydrocarbon such as methane [CH4], ethylene [C2H4] or propane [C3H8] may be used.

A fifth practice which is useful for obtaining a good intrinsic layer provides for heating the substrates evenly while the growth is taking place in a hot-wall reaction chamber, the substrates being preferably arranged substantially horizontal between two substantially horizontal and substantially parallel walls close to each other (e.g. 25-50 mm).

A sixth practice which is useful for obtaining a good intrinsic layer provides for keeping the substrates in rotation while the growth is taking place, the substrates being in particular arranged on a support element, preferably a susceptor.

According to the present invention, these practices, not necessarily all of them, may be advantageously combined together.

Of course, high-purity precursor gases (of carbon and silicon) shall still be used for the epitaxial growth.

It is appropriate that the epitaxial layer grown during process step b) is rather thick, typically between 20 microns and 150 microns.

Since the grown layer is preferably rather thick, the conductive wafer can be rather thin; advantageously, the cost of the conductive wafer and therefore of the product is thus decreased. The thickness of the wafer is typically comprised between 150 microns and 300 microns, and is preferably about 250 microns.

In any case, process step b) may suitably be followed by a step c) consisting in reducing the thickness of the conductive silicon carbide wafer. This reduction is preferably accomplished by means of mechanic techniques, more preferably through “lapping” or “grinding”.

Among other things, this step leads to a reduction in the thermal resistance of the substrate, which is nevertheless already low since the conductive wafer is made of silicon carbide, which is a material having a very high thermal conductivity.

It should be noted that many other process steps may be carried out between process step b) and process step c), e.g. all or many of the process steps required for manufacturing an electronic device.

The thickness reduction may even be such that the conductive silicon carbide wafer is completely eliminated.

It is worth taking into account the fact that in MMICs [Monolithic Microwave Integrated Circuits] it is quite common to provide conductive layers (often made of a metallic material) and “via-hole” type contacts on the back of the substrate. For this purpose, in particular, it may therefore be advantageous that a conductive layer is already present on the back of the substrate, said conductive layer corresponding, in the case of the present invention, to the wafer made of conductive material (possibly reduced in thickness).

As far as sensors are concerned, it is more typical and advantageous to carry out a complete removal of the conductive wafer.

The above-described process allows to produce silicon carbide substrates for electronic applications.

Such a substrate generally comprises:

a) a conductive silicon carbide wafer, and

b) an epitaxial layer of intrinsic silicon carbide on said wafer.

As already mentioned, the thickness of the epitaxial layer is typically comprised between 20 microns and 150 microns.

As already mentioned, the thickness of the original wafer is typically comprised between 150 microns and 300 microns, being preferably about 250 microns. However, since a step for reducing the thickness of the wafer may be included in the process, the wafer in the resulting substrate (if present) may even be thinner, e.g. between 5 microns and 20 microns.

Advantageously, the final substrate can be expected to have an overall thickness between 80 microns and 150 microns.

As already mentioned, if an epitaxial reactor is used which has very good control over the substances introduced into the reaction chamber, the epitaxial layer of intrinsic material will be advantageously free from any substances adapted to compensate for any unintentional doping species in the layer itself.

These substrates allow to manufacture electronic devices adapted in particular to operate at very high frequencies, such as HEMTs; in general, each device will comprise only a portion (“die”) of substrate.

One of the several advantageous applications of the process and substrate according to the present invention consists in the production of HEMTs made of GaN (gallium nitride). In this case, at least one epitaxial layer of typically intrinsic (or very slightly doped) gallium nitride is laid over the epitaxial layer of intrinsic silicon carbide.

Another advantageous application of the process and substrate according to the present invention is the production of high-energy radiation sensors (in particular X-ray sensors) made of GaN. In this case as well, at least one epitaxial layer of gallium nitride is laid over the epitaxial layer of intrinsic silicon carbide.

1. Process for producing a silicon carbide substrate for microelectronic applications, comprising the following steps:
a) providing a conductive silicon carbide wafer, and
b) growing an epitaxial layer of intrinsic silicon carbide on said wafer.

2. Process according to claim 1, wherein said step b) is carried out by means of a CVD technique.

3. Process according to claim 1, wherein said step b) is carried out without using or adding any substances adapted to compensate for any unintentional doping species in the grown layer.

4. Process according to claim 1, wherein the thickness of said wafer is comprised between 150 microns and 300 microns, being preferably about 250 microns.

5. Process according to claim 1, wherein the thickness of said epitaxial layer is comprised between 20 microns and 150 microns.

6. Process according to claim 1, wherein a step c) is carried out after said step b), said step c) consisting in reducing the thickness of said conductive silicon carbide wafer.

7. Silicon carbide substrate for microelectronic applications, comprising:
a) a conductive silicon carbide wafer, and
b) an epitaxial layer of intrinsic silicon carbide on said wafer.

8. Substrate according to claim 7, wherein said epitaxial layer is obtained by means of a CVD technique and is free from any substances adapted to compensate for any unintentional doping species in the layer itself.

9. Substrate according to claim 7, wherein said substrate has a thickness between 80 microns and 150 microns.

10. Substrate according to claim 7, wherein the thickness of said epitaxial layer is comprised between 20 microns and 150 microns.

11. Electronic device according to claim 7 comprising at least one substrate portion.

12. Electronic device according to claim 11, wherein said electronic device is of HEMT type, in particular a HEMT made of GaN.

13. Device according to claim 11, wherein said sensor is a sensor for detecting high-energy radiations, in particular X rays, in particular a sensor made of GaN.

14. The process of claim 1 wherein the intrinsic silicon carbide has doping of less than 1.0E+14 per cubic centimeter.

15. The substrate of claim 7 wherein the intrinsic silicon carbide has doping of less than 1.0E+14 per cubic centimeter.

16. Electronic device according to claim 8 comprising at least one substrate portion.

17. Electronic device according to claim 9 comprising at least one substrate portion.

18. Electronic device according to claim 10 comprising at least one substrate portion.
